(19) United States
(12) Patent Application Publication
(10) Pub. No.: US 2025/0237490 A1
(43) Pub. Date: Jul. 24, 2025

(54) NON-CONTACT WAFER METROLOGY SYSTEM

(71) Applicant: Micron Technology, Inc., Boise, ID (US)

(72) Inventor: Kunal R. Parekh, Boise, ID (US)

(21) Appl. No.: 19/008,422

(22) Filed: Jan. 2, 2025

Related U.S. Application Data
(60) Provisional application No. 63/624,282, filed on Jan. 23, 2024.

(51) Int. Cl. G01B 7/06; G01R 31/265; H01L 21/66

(52) U.S. Cl. CPC G01B 7/08; G01R 31/265; H01L 22/34

(57) ABSTRACT

A capacitance sensing device including a semiconductor wafer having a frontside surface and a backside surface, a plurality of capacitance sensing units disposed close to the frontside surface of the semiconductor wafer, a plurality of first electrodes disposed on the backside surface of the semiconductor wafer, each of the plurality of the first electrodes being aligned to corresponding capacitance sensing unit of the plurality of capacitance sensing units, a first plurality of electrical interconnections connecting each of the plurality of capacitance sensing units to a signal processing circuitry, and a second plurality of electrical interconnections connecting each of the plurality of first electrodes to a power source.

### CROSS-REFERENCE TO RELATED APPLICATION(S)

The present application claims priority to U.S. Provisional Patent Application No. 63/624,282, filed Jan. 23, 2024, the disclosure of which is incorporated herein by reference in its entirety.

### TECHNICAL FIELD

The present disclosure generally relates to semiconductor wafer metrology, and more particularly relates to a non-contact wafer metrology system for wafer thickness measurement and voids inspection.

### BACKGROUND

Wafer metrology is a critical process in semiconductor manufacturing as it ensures the quality and reliability of integrated circuits by measuring various parameters of a semiconductor wafer. In advanced semiconductor memory device fabrication that involves bonding of ultra-thin silicon wafer between wafers or attached to carriers, wafer metrology is widely adopted to measure the wafer thickness and inspect voids. Conventional methods for wafer thickness measurement and void inspection in semiconductor manufacturing involves the physical contact of a probe or stylus with the wafer's surface to make precise measurements. These measurements can potentially damage the wafer's surface and affect the final device yield. Semiconductor manufacturers often employ a combination of metrology methods to ensure a highly precise and reliable measurement on their semiconductor wafers.

### BRIEF DESCRIPTION OF THE DRAWINGS

FIG. 1 depicts a schematic view of a non-contact semiconductor wafer metrology system in accordance with embodiments of the present technology.

FIG. 2 depicts a schematic diagram of a capacitance sensing unit in accordance with embodiments of the present technology.

FIGS. 3A and 3B depict a schematic view of a non-contact semiconductor wafer metrology system and a corresponding circuit diagram respectively in accordance with embodiments of the present technology.

FIGS. 3C and 3D depict a schematic view of another non-contact semiconductor wafer metrology system and a corresponding circuit diagram respectively in accordance with embodiments of the present technology.

FIGS. 4A and 4B depict various patterns of capacitance sensing units disposed on a capacitance sensing wafer of a non-contact semiconductor wafer metrology system in accordance with embodiments of the present technology.

FIG. 5 depicts a perspective view of a non-contact semiconductor wafer metrology system filled with a working gas in accordance with embodiments of the present technology.

FIG. 6 is a flow chart illustrating a method of semiconductor wafer measurement and inspection in accordance with embodiments of the present technology.

FIG. 7 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

Bonding ultra-thin silicon wafers between wafers or attaching them to carrier wafers plays a crucial role in many advanced semiconductor devices, such as advanced memory and logic device integration, particularly in semiconductor manufacturing for memory and logic devices. This technique is commonly used to enable 3D integration, package stacking, and heterogeneous device integration. The bonding of ultra-thin silicon wafers requires thickness measurement of the wafer to ensure precision and quality control during the bonding process. Typically, specialized metrology equipment is used for measuring ultra-thin wafers thickness and inspecting the wafers, such as a stylus profilometer, optical interferometer, atomic force microscopy (AFM), or ellipsometer. These technologies are complex and with many limitations. For example, AFM is a slow imaging technique operated by scanning a sharp tip across the wafer surface. It can be time-consuming and not suitable for measuring the thickness variation across an entire wafer due to its relatively small field of view. Moreover, AFM measurements may apply a force to the sample during scanning, potentially causing damages or deformation to the wafer's surface. In another example, optical interferometry relies on an interference of light waves with a wafer under test. The accuracy of the measurement is degraded when the wavelength is not precisely known or when the wafer material's refractive index changes with light wavelength. In addition, optical interferometry is most suitable for measuring the thickness of transparent or semi-transparent wafers. It is less effective for opaque or highly reflective wafers because the interference patterns may not be detectable on the wafer. Therefore, there is a need of non-contact wafer metrology technique for across wafer thickness measurement and inspections.

The present technology provides a capacitance sensing array wafer that can be adopted for high resolution wafer thickness and defects inspection. Specifically, the capacitance sensing array wafer can be disposed parallel to a testing semiconductor wafer and have a group of capacitance sensing units disposed on a top surface of the capacitance sensing array wafer. Each of the group of capacitance sensing units can measure a capacitance of corresponding area of the testing semiconductor wafer. In particular, the capacitance sensing array wafer can measure electrical charges cumulated in the testing semiconductor wafer and a gap between the testing semiconductor wafer and the capacitance sensing array wafer. Additionally, the capacitance sensing array wafer can measure charges accumulated in the gap region only, therefore referring a capacitance of corresponding area of the testing semiconductor wafer. Cross wafer thickness information and wafer defects such as voids can be further estimated based on the calculated capacitance of corresponding area of the testing semiconductor wafer. In addition, the present technology can also utilize an inductance sensing array wafer, for the purposes of wafer thickness and defects measurement through detecting the inductance of a testing semiconductor wafer.

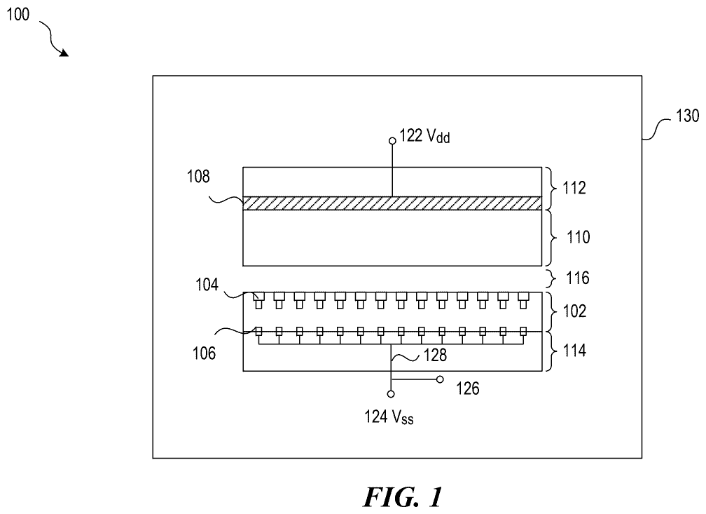

FIG. 1 shows a schematic view of a non-contact semiconductor wafer metrology system 100 in accordance with embodiments of the present technology. As shown, the non-contact semiconductor wafer metrology system 100 includes a capacitance sensing array wafer 102 and a testing semiconductor wafer 110. The capacitance sensing array wafer 102 and the testing semiconductor wafer 110 are disposed in parallel and facing to each other. In addition, the capacitance sensing array wafer 102 and the testing semiconductor wafer 110 are separated by a gap 116 and disposed on a bottom chuck 114 and a top chuck 112, respectively. The non-contact semiconductor wafer metrology system 100 also includes a chamber 130 within which the capacitance sensing array wafer 102, the testing semiconductor wafer 110, the top chuck 112, and the bottom chuck 114 are disposed.

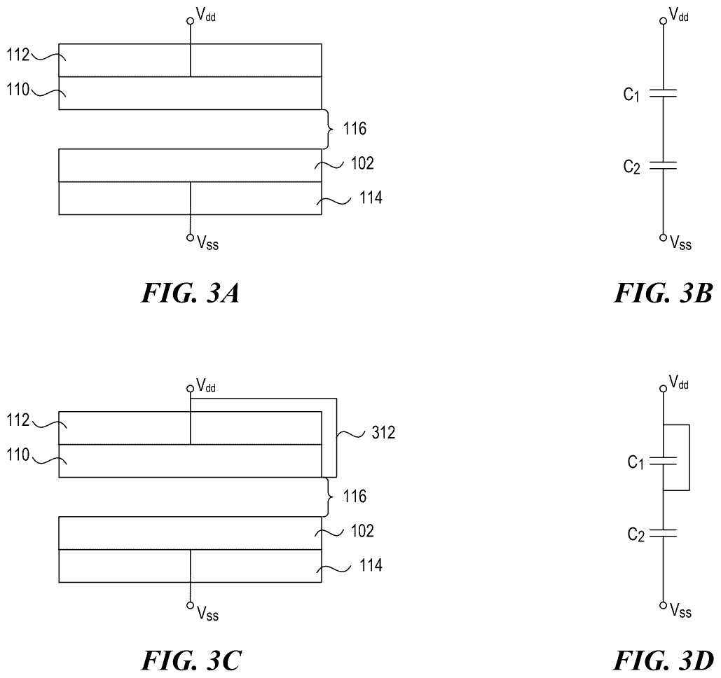

In this example, the capacitance sensing array wafer 102 can have its backside surface connected to the bottom chuck 114 and have its frontside surface facing the testing semiconductor wafer 110. Further, the testing semiconductor wafer 110 can have its backside surface connected to the top chuck 112 and have its frontside surface facing the capacitance sensing array wafer 102. As shown in FIG. 1, the capacitance sensing array wafer 102 includes a group of capacitance sensing units 104 disposed on its frontside surface. The group of capacitance sensing units 104 can be aligned in various pattern on the capacitance sensing array wafer, e.g., in a circular pattern, in square pattern, or in a grid pattern. Detailed description of exemplary alignments of the capacitance sensing units 104 is provided in FIGS. 3A and 3B. In this example, the group of capacitance sensing units 104 are configured to measure capacitances between the capacitance sensing array wafer 102 and the testing semiconductor wafer 110. For example, the group of capacitance sensing units 104 can detect a first capacitance existed between the frontside surface of the capacitance sensing array wafer 102 and the bottom surface (e.g., frontside surface) of the testing semiconductor wafer 110. Moreover, the group of capacitance sensing units 104 can measure a second capacitance existed between the frontside surface of the capacitance sensing array wafer 102 and the top surface (e.g., backside surface) of the testing semiconductor wafer 110. Each of the group of capacitance sensing units 104 may have a horizontal dimension ranging from 1 μm to 1 mm. In this example, the capacitance sensing array wafer 102 may include up to hundreds thousands of capacitance sensing units.

As shown in FIG. 1, the capacitance sensing array wafer 102 also includes a group of bottom electrodes disposed on its backside surface. Each of the group of bottom electrodes 106 is electrically connected with corresponding capacitance sensing unit of the group of capacitance sensing units 104, within the capacitance sensing array wafer 102. The group of bottom electrodes 106 are configured to transmit electrical signals from and power supplies to the capacitance sensing unit 104. In particular, electrical signals of the capacitance sensing units 104 can be transmitted out of the non-contact semiconductor wafer metrology system 100 through the output terminal 126. In this example, each of the group of bottom electrodes 106 can be made of electrically conductive materials including aluminum, copper, titanium, gold, platinum, nickel, tungsten, or a combination thereof. In this example, the testing semiconductor wafer 110 includes a plurality of semiconductor dies, and one or more capacitance sensing units of the group of capacitance sensing units 104 are aligned to a corresponding semiconductor die of the testing semiconductor wafer 110.

In this example, electrical power sources are included in the non-contact semiconductor wafer metrology system 100 for wafer thickness measurement and inspections. For example, a positive supply voltage V_{dd} 122 can be connected to the top chuck to provide a positive voltage to the testing semiconductor wafer 110. In addition, a negative supply voltage or ground Vₛₛ 124 can be connected to the bottom chuck and provide a negative or ground voltage level to the capacitance sensing array wafer 102. In some other examples, the positive supply voltage V_{dd} 122 can be connected to the capacitance sensing array wafer 102 through the bottom chuck and the negative supply voltage or ground Vₛₛ 124 can be connected to the testing semiconductor wafer 110 through the top chuck. In this example, the supply voltage levels of the V_{dd} 122 and Vₛₛ 124 may ranging from −5V to +5V. As shown in FIG. 1, each of the group of capacitance sensing unit 104 is connected to the negative supply voltage or ground Vₛₛ through electrical interconnections.

In the present technology, the sensitivity of wafer thickness and defects measurements can be adjusted through modifying the difference between the positive supply voltage V_{dd} 122 and the negative supply voltage or ground Vₛₛ 124. For example, a larger voltage difference (e.g., “V_{dd}−Vₛₛ” equals to 10V, 20V, or 30V) may be provided to achieve a greater sensitivity towards capacitance variations of the testing semiconductor wafer 110 and, therefore, greater sensitivity to its thickness variation. In contrast, a smaller voltage difference (“V_{dd}-Vₛₛ” equals to 1V, 2V, or 5V) may be configured to provide a lesser sensitivity towards capacitance variations and, therefore, lesser sensitivity to thickness variations.

As shown in FIG. 1, the non-contact semiconductor wafer metrology system 100 includes a top electrode 108 that is disposed on the bottom surface of the top chuck 112 and connected to the testing semiconductor wafer 110. The top electrode 108 is a continuous layer made of electrically conductive materials including aluminum, copper, titanium, gold, platinum, nickel, tungsten, or a combination thereof. In some other examples, the non-contact semiconductor wafer metrology system 100 can include a group of top electrodes aligned in a certain pattern (e.g., in a circular pattern, in square pattern, or in a grid pattern) and disposed on the backside surface of the top chuck 112. Each of the group of top electrodes can be aligned with corresponding capacitance sensing unit of the capacitance sensing array wafer 102.

In the non-contact semiconductor wafer metrology system 100, the capacitance sensing array wafer 102 can have a same size with the testing semiconductor wafer 110. For example, both capacitance sensing array wafer 102 and the testing semiconductor wafer 110 can have a diameter of 12 inches. In some other example, the capacitance sensing array wafer 102 may have a size different to that of the testing semiconductor wafer 110. For example, the capacitance sensing array wafer 102 can be a 12 inch wafer and the testing semiconductor wafer 110 can be an 8 inch wafer or a 5 inch wafer. Alternatively, the testing semiconductor wafer 110 may have a size larger than the capacitance sensing array wafer 102. In this case, the capacitance sensing array wafer can be horizontally moved, e.g., by a motor coupled to the bottom chuck 114, to collect capacitance data across the whole wafer surface of the testing semiconductor wafer 110. In addition, the capacitance sensing array wafer 102 can be made of semiconductor material such as silicon, germanium, gallium arsenide, gallium nitride, indium phosphide, silicon carbide, silicon germanium, and/or a combination thereof. In some other examples, the capacitance sensing array wafer 102 can be made of III-V semiconductor compound materials.

In the non-contact semiconductor wafer metrology system 100, the capacitance sensing array wafer 102 and the testing semiconductor wafer 110 are securely held by the bottom chuck 114 and top chuck 112, respectively. The bottom chuck 114 and top chuck 112 are configured to hold the capacitance sensing array wafer 102 and the testing semiconductor wafer 110 in place during the metrology measurement process. Here, various chucks can be adopted into the chamber 130 of the non-contact semiconductor wafer metrology system 100, including mechanical chucks using physical clamping mechanisms and vacuum chucks using suction to hold wafers in place. Before the metrology process starts, the capacitance sensing array wafer 102 and the testing semiconductor wafer 110 are carefully aligned and positioned to corresponding check to ensure that they are centered and orientated correctly. Once the metrology process completed, the top chuck 112 is designed to gently release the testing semiconductor wafer 110 without electrostatic attraction. In some examples, the capacitance sensing array wafer 102 can be also released from the bottom chuck 114, e.g., for maintenance purpose and others. In some other embodiments, the non-contact semiconductor wafer metrology system 100 may include a capacitance sensing array panel that is parallelly aligned with the testing semiconductor wafer 110 for wafer thickness measurement and defects detection. Accordingly, the bottom chuck 114 can be modified to suit to the capacitance sensing array panel.

In this example, the components of the non-contact semiconductor wafer metrology system 100 can be disposed in the chamber 130. The chamber 130 can be a vacuum chamber equipped with a vacuum pump to achieve and maintain a desired level of vacuum for the wafer thickness measurement and inspection. The chamber 130 may include a gas inlet to introduce various working gases therein. In this example, the components of the non-contact semiconductor wafer metrology system 100 may also include a signal processing circuitry that is configured to receive electrical signals generated from the capacitance sensing array wafer 102. For example, the AC signal variation from each of the group of capacitance sensing units 104 can be transmitted through the output terminal 126 to the signal processing circuitry for wafer thickness conversion. Here, the signal processing circuitry can be disposed inside the chamber 130 or coupled to the chamber 130 through electrical interconnections. In this example, the non-contact semiconductor wafer metrology system 100 may include a switch circuitry connected to each of the electrical interconnections 128, the switch circuitry being configured to switch on/off the electrical interconnections between the power source Vₛₛ 124 and corresponding capacitance sensing units 104. In the present technology, the capacitance sensing array wafer 102 is detachable from the bottom chuck 114. Once the thickness measurement and wafer inspection are completed, the capacitance sensing array wafer 102 can be removed from the chamber 130 of the non-contact semiconductor wafer metrology system 100, and measurement data can be pull out from the group of capacitance sensing units 140 for further processing.

In some other embodiments, the non-contact semiconductor wafer metrology system 100 can be configured to measure inductance of a testing semiconductor wafer. For example, an inductance sensing array wafer 102 and the testing semiconductor wafer 110 can be securely held by the bottom chuck 114 and top chuck 112 respectively, as shown in FIG. 1. The inductance sensing array wafer 102 can include a group of inductance sensing unit 104 for corresponding inductance measurement on the testing semiconductor wafer 110.

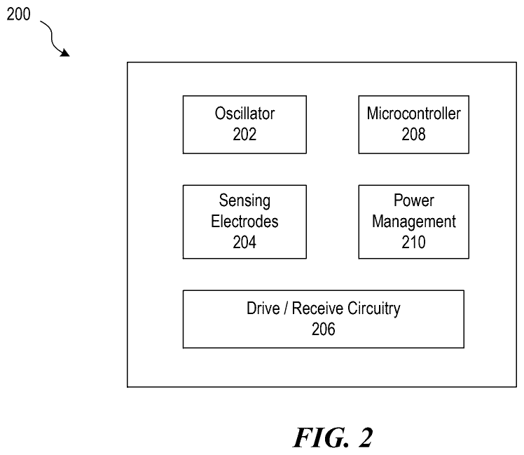

FIG. 2 depicts a schematic diagram of a capacitance sensing unit 200 in accordance with embodiments of the present technology. The capacitance sensing unit 200 can be identical to each capacitance sensing unit of the group of capacitance sensing units 104 described in FIG. 1. The capacitance sensing unit 200 can included multiple components including an oscillator 202, one or more sensing electrodes 204, a drive and receive circuitry 206, a microcontroller 208 and a power management module 210. In this example, the capacitance sensing unit 200 can generate, by the oscillator 202, an alternating current (AC) signal and apply the AC signal to the one or more sensing electrodes 204 to form a basis for capacitance measurement. The one or more sensing electrodes 204 can be made of electrically conductive materials such as metals and interact with external environment (e.g., the gap 116 and/or the testing semiconductor wafer 110). In addition, the capacitance sensing unit 200 employs the drive and receive circuitry 206 to generate the AC signal and applies the signal to the one or more sensing electrodes 204. The drive and receive circuitry 206 also measures the capacitance changes by monitoring changes in the amplitude, phase, and/or frequency of the AC signal. In this example, the measured capacitance data is fed into the microcontroller 208 for further analysis. The microcontroller 208 can delivery the process capacitance data to an outside circuitry through the output terminal 126 of the non-contact semiconductor wafer metrology system 100. Here, the capacitance sensing unit 200 can also include a power management module 210 to ensure efficient operation and minimize power consumption when the capacitance sensing unit 200 is idle. In some other examples, the group of capacitance sensing units 104 can share a microcontroller and/or a power management module that are disposed in the capacitance sensing array wafer 102 for the wafer thickness measurement and wafer inspection.

In the present technology, the thickness of the testing semiconductor wafer 110 is estimated by operating the group of capacitance sensing units 104 of the capacitance sensing array wafer 102. In particular, the non-contact semiconductor wafer metrology system 100 charges the testing semiconductor wafer 110, the capacitance sensing array wafer 102, and the gap 116 disposed therebetween with an AC current. This current flows into the testing semiconductor wafer 110 and the capacitance sensing array wafer 102, causing charge accumulation on the wafers. As the testing semiconductor wafer 110 gets charged, the accumulation of electric charge results in an increase in voltage across it. The rate of voltage increase can be determined by the capacitance of the testing semiconductor wafer 110. The greater the capacitance, the slower the voltage rise for a given AC current. In this example, the group of capacitance sensing units 104 detects the capacitance of the testing semiconductor wafer and the gap 116 using a known current and a rate of voltage increase. Specifically, the capacitance of the testing semiconductor wafer 110 (including the gap 116) is directly proportional to a charge (Q) and inversely proportional to the voltage change (AV) during charging, as described by the formula: C=Q/AV. Moreover, the detected capacitance of the testing semiconductor wafer 110 can be converted to a thickness value. For example, the capacitance of testing semiconductor wafer 110 is influenced by its dielectric properties, a surface area (e.g., surface area of one of the group of capacitance sensing units 104), and the distance between the material and the reference electrode. Here, the distance is calculated from a frontside surface to a backside surface of the testing semiconductor wafer 110, and/or from the backside surface of the testing semiconductor wafer 110 to the frontside surface of the capacitance sensing array wafer 102 (i.e., the distance of gap 116). Once the capacitance is measured by the group of capacitance sensing units 104, corresponding thickness values can be calculated to infer the testing semiconductor wafer 110's thickness.

In the present technology, defects such as voids embedded the testing semiconductor wafer 110 can be estimated through the wafer thickness measurement. For example, wafer thickness at various points of the testing semiconductor wafer can be measured using the non-contact semiconductor wafer metrology system 100. Once a baseline thickness and a wafer thickness profile are established, a further wafer thickness analysis can be conducted to identify deviations from the wafer baseline thickness. By looking for regions where the wafer thickness is significantly different from adjust regions or the expected baseline value, a wafer void defect can be inspected.

FIGS. 3A and 3B show a schematic view of first non-contact semiconductor wafer metrology system configuration and a corresponding circuit diagram respectively in accordance with embodiments of the present technology. As shown in FIG. 3A, the capacitance sensing array wafer 102 is disposed on the bottom chuck 114 and facing to the testing semiconductor wafer 110 which is disposed on the top chuck. Supply voltages and ground are connected to the capacitance sensing array wafer 102 and the testing semiconductor wafer 110 through corresponding chucks. In particular, the positive supply voltage V_{dd} is connected to the top surface of the testing semiconductor wafer 110 and negative supply voltage or ground Vₛₛ is connected to the bottom surface of the capacitance sensing array wafer 102. Once the non-contact metrology operation starts, a current can flow into the testing semiconductor wafer 110 and the capacitance sensing array wafer 102, causing charge accumulation on the wafers. In this example, charges can be accumulated between the top surface of the testing semiconductor wafer 110 and the top surface of the capacitance sensing array wafer 102, i.e., the space through the testing semiconductor wafer 110 and the gap 116. A capacitance corresponding to the cumulated charges can be measured by the group of capacitance sensing units 104 of the non-contact semiconductor wafer metrology system 100.

FIG. 3B illustrates a circuit diagram corresponding to the non-contact semiconductor wafer metrology system 100 of FIG. 3A. In this example, the testing semiconductor wafer 110 reveals a first capacitor C1 and the gap 116 reveals a second capacitor C2. The first capacitor C1 and the second capacitor C2 are connected in serial and between the positive supply voltage V_{dd} and the negative supply/ground Vₛₛ. Here, the group of capacitance sensing units 104 of the non-contact semiconductor wafer metrology system 100 can be configured to measure a total capacitance of the testing semiconductor wafer 110 and the gap 116, e.g., a sum of C1 and C2.

FIGS. 3C and 3D show a schematic view of a second non-contact semiconductor wafer metrology system configuration and a corresponding circuit diagram respectively in accordance with embodiments of the present technology. As shown in FIG. 3C, the capacitance sensing array wafer 102 is disposed on the bottom chuck 114 and facing to the testing semiconductor wafer 110 which is disposed on the top chuck. Supply voltages and ground are connected to the capacitance sensing array wafer 102 and the testing semiconductor wafer 110 through corresponding chucks. In particular, the second non-contact semiconductor wafer metrology system includes an electrical interconnection 312 which interconnects the bottom surface of the testing semiconductor wafer 110 with the positive voltage supply V_{dd}. As shown, the electrical interconnection 312 shorts the testing semiconductor wafer 110 from the positive voltage supply V_{dd}. Once the non-contact metrology operation starts, a charge accumulation can only happen across the gap 116. As shown in FIG. 3D, the first capacitor is shorted between the positive supply voltage V_{dd} and the negative supply/ground Vₛₛ. The group of capacitance sensing units 104 of the non-contact semiconductor wafer metrology system 100 can measure an individual capacitance C2 of the gap 116.

In the present technology, the non-contact semiconductor wafer metrology system 100 further includes the electrical interconnection 312 which electrically connects the positive voltage supply V_{dd} with the bottom surface of the testing semiconductor wafer 110. Moreover, the non-contact semiconductor wafer metrology system 100 can be configured to switch on and off the electrical interconnection 312, to exchange between the first and second non-contact semiconductor wafer metrology system configurations. As described above, a sum capacitance of C1 and C2 can be measured in the first non-contact semiconductor wafer metrology system configuration. An individual capacitance of C2 can be measured in the second non-contact semiconductor wafer metrology system configuration. Once these data are collected, the capacitance sensing array wafer 102 or the signal processing circuitry electrically connected to the capacitance sensing array wafer 102 can further process the capacitance C1 of the testing semiconductor wafer 110, e.g., by subtracting C2 from the sum capacitance of C1 and C2. After that, a thickness of the testing semiconductor wafer 110 can be calculated referencing to the dielectric properties (e.g., a dielectric constant of material forming the testing semiconductor wafer), and a surface area value (e.g., surface area of corresponding one of the group of capacitance sensing units 104 for the capacitance measurement).

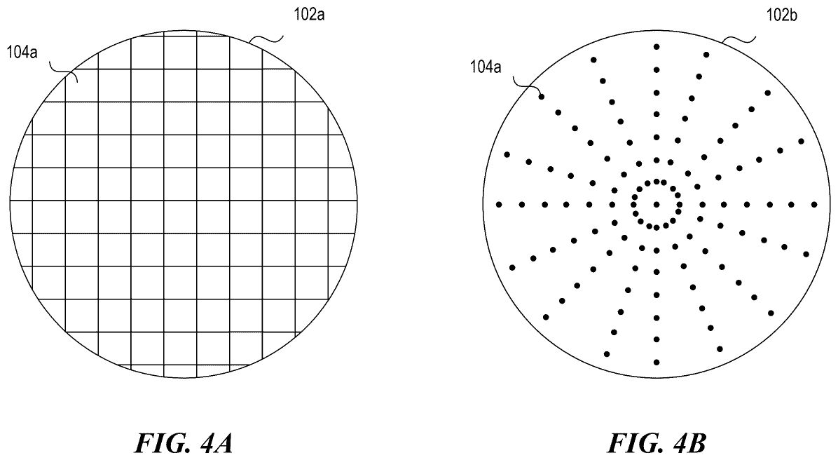

The wafer thickness measurement and voids inspection of the present technology can achieve a high resolution by configurating the group of capacitance sensing units 104 in various arrays on the capacitance sensing array wafer 102. For example, besides scaling the electrode dimension of each of the group of capacitance sensing units 104 to detect thickness of an area of testing semiconductor wafer in micrometer scale or less, the profile and position of each capacitance sensing unit can be adjusted in accordance with the measurement requirements. FIG. 4A shows a checkboard pattern of the group of capacitance sensing units 104a disposed on a capacitance sensing array wafer 102a in accordance with embodiments of the present technology. In this configuration, alternating regions of capacitance sensing units 104a and gaps can be aligned in a checkerboard fashion. This checkboard pattern of capacitance sensing units can provide a straightforward references for calibration and alignment. In another example, FIG. 4B shows a radial line pattern of the group of capacitance sensing units 104b disposed across a wafer surface of a capacitance sensing wafer 102b in accordance with embodiments of the present technology. In this configuration, capacitance sensing units 104b are aligned in straight lines extending from the center to the edge of the capacitance sensing wafer 102b. This radial line pattern of capacitance sensing units is useful in capturing radial variations and identifying defects (e.g., voids) along specific paths in the testing semiconductor wafer. In some other examples, the group of capacitance sensing units can be arranged in patterns including grid array, concentric circles, spiral pattern, random pattern, diamond pattern, or a combination thereof.

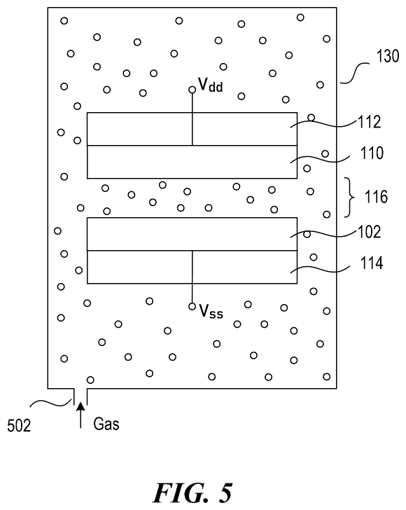

In the present technology, one or more working gases can be introduced into the non-contact semiconductor wafer metrology system for wafer thickness and inspections. As described earlier, the group of capacitance sensing units can measure the sum capacitance of the testing semiconductor wafer and the gap between the testing semiconductor wafer and the capacitance sensing array wafer. Since the dielectric constant of the gap (e.g., 1.00059 for air) is much lower than the semiconductor wafer (12 for silicon), the measured gap capacitance (e.g., C2 of FIG. 3D) in general less dominates the measure sum capacitance (e.g., sum of C1 and C2 of FIG. 3B). A working gas can be introduced into the gap to adjust the ratio of gap capacitance to the sum capacitance, in order to improve the capacitance measurement accuracy. As shown in FIG. 5, the semiconductor wafer metrology system 100 of the present technology can further include a gas inlet 502 that is disposed on the chamber 130. A working non-reactive gas such as nitrogen, argon, helium, xenon, neon, carbon dioxide, hydrogen, methane, or a combination thereof can be introduced in the gap 116 between the capacitance sensing array wafer 102 and the testing semiconductor wafer 110. With this configuration, the present technology can eliminate measurement noise during the metrology operation. For example, the semiconductor wafer metrology system 100 can introduce a working gas with a known dielectric properties to the gap 116, and then calibrate the capacitance measurement by comparing a measured gap capacitance based on the known dielectric properties of the working gas.

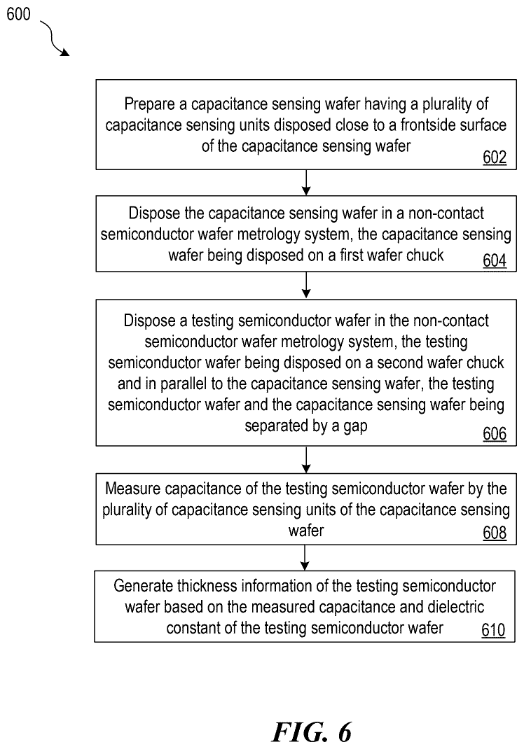

Turning now to FIG. 6 which is a flow chart illustrating a method 600 of semiconductor wafer measurement and inspection in accordance with embodiments of the present technology. The method 600 includes preparing a capacitance sensing wafer having a plurality of capacitance sensing units disposed close to a frontside surface of the capacitance sensing wafer, at 602. For example, the non-contact semiconductor wafer metrology system 100 described in FIG. 1 can be adopted for the wafer measurement and inspection. In particular, the capacitance sensing array wafer 102 can be included therein for capacitance measurement. The capacitance sensing array wafer 102 has a group of capacitance sensing units 104 that are disposed on its frontside surface and configured to measure capacitance of corresponding area on the testing sample wafer 110.

The method 600 also includes disposing the capacitance sensing wafer in a non-contact semiconductor wafer metrology system, the capacitance sensing wafer being disposed on a first wafer chuck, at 604. For example, the testing semiconductor wafer 110 can be loaded into the non-contact semiconductor wafer metrology system 100. Specifically, the testing semiconductor wafer 110 can be held by the top chuck 112.

In addition, the method 600 includes disposing a testing semiconductor wafer in the non-contact semiconductor wafer metrology system, the testing semiconductor wafer being disposed on a second wafer chuck and in parallel to the capacitance sensing wafer, the testing semiconductor wafer and the capacitance sensing wafer being separated by a gap, at 606. For example, the capacitance sensing array wafer 102 can be loaded into the non-contact semiconductor wafer metrology system 100. In particular, the capacitance sensing array wafer 102 can be held by the bottom chuck 114 and aligned parallel to the testing semiconductor wafer 110.

Further, the method 600 includes measuring capacitance of the testing semiconductor wafer by the plurality of capacitance sensing units of the capacitance sensing wafer, at 608. For example, each of the group of capacitance sensing units 104 of the capacitance sensing array wafer 102 can be activated to measure thickness of corresponding areas of the testing semiconductor wafer 110. Specifically, power supply voltages can be applied on the testing semiconductor wafer 110 and the capacitance sensing array wafer 102 to accumulate charges for the capacitance measurement.

Lastly, the method 600 includes generating thickness information of the testing semiconductor wafer based on the measured capacitance and dielectric constant of the testing semiconductor wafer, at 610. For example, the group of capacitance sensing units 104 of the capacitance sensing array wafer 102 or the signal processing circuit coupled to the capacitance sensing array wafer 102 can be configured to calculate the thickness of the testing semiconductor wafer based on the measured capacitance and dielectric properties of the testing semiconductor wafer 110.

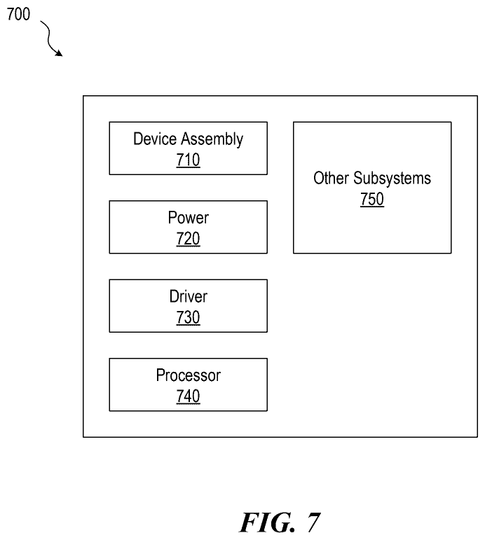

Any one of the semiconductor structures described above with reference to FIGS. 1 to 6 can be incorporated into any of a myriad of larger and/or more complex systems, a representative example of which is system 700 shown schematically in FIG. 7. The system 700 can include a semiconductor device assembly 710, a power source 720, a driver 730, a processor 740, and/or other subsystems or components 750. The semiconductor device assembly 710 can include features generally similar to those of the semiconductor device assemblies described above, and can therefore include the non-contact semiconductor wafer metrology system described in the present technology. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, and appliances. Components of the system 700 may be housed in a single unit or distributed over multiple, interconnected units (e.g., through a communications network). The components of the system 700 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A capacitance sensing device, comprising:
a semiconductor wafer having a frontside surface and a backside surface;
a plurality of capacitance sensing units disposed close to the frontside surface of the semiconductor wafer;
a plurality of first electrodes disposed on the backside surface of the semiconductor wafer, each of the plurality of the first electrodes being aligned to corresponding capacitance sensing unit of the plurality of capacitance sensing units;
a first plurality of electrical interconnections connecting each of the plurality of capacitance sensing units to a signal processing circuitry; and
a second plurality of electrical interconnections connecting each of the plurality of first electrodes to a power source.

2. The capacitance sensing device of claim 1, further comprising:
one or more second electrodes disposed on a testing sample; and
a third plurality of electrical interconnections connecting each of the one or more second electrodes to the power source.

3. The capacitance sensing device of claim 2, further comprising a switch circuitry connecting to each of the second plurality of electrical interconnections and/or the third plurality of electrical interconnections, the switch circuitry being configured to switch on/off the electrical interconnections between the power source and the plurality of first electrodes and/or between the power source and the one or more second electrodes.

4. The capacitance sensing device of claim 2, wherein the capacitance sensing device is configured to charging, by the power source, the testing sample with a current and measuring, by the signal processing circuitry, a resulting voltage.

5. The capacitance sensing device of claim 3, wherein the switch circuitry is embedded in the semiconductor wafer.

6. The capacitance sensing device of claim 1, wherein the plurality of capacitance sensing units are embedded in the semiconductor wafer.

7. The capacitance sensing device of claim 1, wherein each of the plurality of capacitance sensing units includes one or more capacitance sensors or a capacitance sensing circuitry.

8. A non-contact semiconductor wafer metrology system, comprising:
a capacitance sensing wafer, comprising:
a plurality of capacitance sensing units disposed close to a frontside surface of the capacitance sensing wafer, and
a plurality of first electrodes disposed on a backside surface of the capacitance sensing wafer, each of the plurality of first electrodes being aligned to corresponding capacitance sensing unit of the plurality of capacitance sensing units,
a testing semiconductor wafer disposed in parallel to the capacitance sensing wafer, the testing semiconductor wafer and the capacitance sensing wafer being separated by a gap;
one or more second electrodes disposed above the testing semiconductor wafer; and
a power source electrically connected to the plurality of first electrodes of the capacitance sensing wafer and the one or more second electrodes of the testing semiconductor wafer.

9. The non-contact semiconductor wafer metrology system of claim 8, further comprising:
a first wafer chuck on which the capacitance sensing wafer is disposed;
a second wafer chuck on which the testing semiconductor wafer is disposed;
a signal processing circuitry connected to each of the plurality of capacitance sensing units of the capacitance sensing wafer; and
a switch circuitry connected to each of the plurality of first electrodes and the one or more second electrodes.

10. The non-contact semiconductor wafer metrology system of claim 8, wherein a backside surface of the testing semiconductor wafer is facing towards the frontside surface of the capacitance sensing wafer, the backside surface of the testing semiconductor wafer and the frontside surface of the capacitance sensing wafer being separated by the gap.

11. The non-contact semiconductor wafer metrology system of claim 9, wherein the testing semiconductor wafer includes a stack of a carrier wafer and a product wafer, the product wafer is attached to the carrier wafer, the one or more second electrodes are disposed on the carrier wafer, and a frontside surface of the product wafer is facing towards the frontside surface of the capacitance sensing wafer.

12. The non-contact semiconductor wafer metrology system of claim 11, wherein the plurality of capacitance sensing units of the capacitance sensing wafer are configured to measure a first capacitance between the carrier wafer and the capacitance sensing wafer.

13. The non-contact semiconductor wafer metrology system of claim 11, wherein the plurality of capacitance sensing units of the capacitance sensing wafer are configured to measure a second capacitance between the product wafer and the capacitance sensing wafer through shorting the carrier wafer and the product wafer.

14. The non-contact semiconductor wafer metrology system of claim 8, wherein the testing semiconductor wafer includes a plurality of semiconductor dies, and one or more capacitance sensing units of the plurality of capacitance sensing units are aligned to a corresponding semiconductor die of the testing semiconductor wafer.

15. The non-contact semiconductor wafer metrology system of claim 8, further comprising one or more inert gases that are disposed in the gap between the testing semiconductor wafer and the capacitance sensing wafer, wherein the one or more inert gases comprise nitrogen, argon, helium, hydrogen, and a combination thereof.

16. A method for semiconductor wafer inspection, comprising:
preparing a capacitance sensing wafer having a plurality of capacitance sensing units disposed close to a frontside surface of the capacitance sensing wafer;
disposing the capacitance sensing wafer in a non-contact semiconductor wafer metrology system, the capacitance sensing wafer being disposed on a first wafer chuck;
disposing a testing semiconductor wafer in the non-contact semiconductor wafer metrology system, the testing semiconductor wafer being disposed on a second wafer chuck and in parallel to the capacitance sensing wafer, the testing semiconductor wafer and the capacitance sensing wafer being separated by a gap;
measuring capacitance of the testing semiconductor wafer by the plurality of capacitance sensing units of the capacitance sensing wafer; and
generating thickness information of the testing semiconductor wafer based on the measured capacitance and dielectric constant of the testing semiconductor wafer.

17. The method of claim 16, further comprising:
disassembling the capacitance sensing wafer from the non-contact semiconductor wafer metrology system; and
outputting measured capacitance information from capacitance sensing wafer to a signal processing circuitry,
wherein the thickness information of the testing semiconductor wafer is generated by a processor connected to the capacitance sensing wafer.

18. The method of claim 16, wherein the testing semiconductor wafer comprises a stack of a carrier wafer and a product wafer, and wherein measuring capacitance of the testing semiconductor wafer comprises:
measuring a first capacitance between the carrier wafer and the capacitance sensing wafer, and
measuring a second capacitance between the product wafer and the capacitance sensing wafer through shorting the carrier wafer and the product wafer.

19. The method of claim 18, wherein measuring capacitance of the testing semiconductor wafer further comprises calculating a third capacitance between the carrier wafer and the product wafer by subtracting the second capacitance between the product wafer and the capacitance sensing wafer from the first capacitance between the carrier wafer and the capacitance sensing wafer.

20. The method of claim 16, further comprises:
injecting one or more inert gases to the gap between the testing semiconductor wafer and the capacitance sensing wafer, wherein the one or more inert gases comprise nitrogen, argon, helium, hydrogen, and a combination thereof;
measuring an updated capacitance of the testing semiconductor wafer by the plurality of capacitance sensing units of the capacitance sensing wafer; and
calibrating the generated thickness information of the testing semiconductor wafer based on the measured capacitance and updated capacitance of the testing semiconductor wafer.
